(19) United States
(12) Patent Application Publication
(10) Pub. No.: US 2026/0164857 A1
(43) Pub. Date: Jun. 11, 2026

(54) OPTOELECTRONIC SEMICONDUCTOR COMPONENT AND METHOD FOR MANUFACTURING AN OPTOELECTRONIC SEMICONDUCTOR COMPONENT

(71) Applicant: ams-OSRAM International GmbH, Regensburg (DE)

(72) Inventor: Tansen Varghese, Regensburg (DE)

(21) Appl. No.: 18/707,778

(22) PCT Filed: Nov. 4, 2022
(86) PCT No.: PCT/EP2022/080802

§ 371 Date: May 6, 2024

(30) Foreign Application Priority Data
Nov. 9, 2021 (DE) 10 2021 129 100.3

(51) Int. Cl. H10H 20/816; H10H 20/819; H10H 29/14

(52) U.S. Cl. CPC H10H 20/8162; H10H 20/819; H10H 29/14

(57) ABSTRACT

In an embodiment an optoelectronic semiconductor component includes a semiconductor body having a first semiconductor layer, a first cladding layer, a second semiconductor layer, a second cladding layer, an active region arranged between the first cladding layer and the second cladding layer, and a blocking layer arranged between the second cladding layer and the second semiconductor layer, wherein the active region is configured to emit an electromagnetic radiation in an emission region, wherein the first semiconductor layer has a first conductivity type, wherein the second semiconductor layer has a second conductivity type, wherein the first cladding layer and the second cladding layer are nominally undoped, wherein the blocking layer is formed of a semiconductor material and configured to confine an operating current of the active region to a core region, and wherein the second semiconductor layer extends at least partially through the blocking layer to the second cladding layer in the core region, which is spaced apart from lateral edges of the emission region.

### CROSS-REFERENCE TO RELATED APPLICATIONS

This patent application is a national phase filing under section 371 of PCT/EP2022/080802, filed Nov. 4, 2022, which claims the priority of German patent application 102021129100.3, filed Nov. 9, 2021, each of which is incorporated herein by reference in its entirety.

### TECHNICAL FIELD

The present application relates to an optoelectronic semiconductor component and a method for manufacturing an optoelectronic semiconductor component.

### SUMMARY

Embodiments provide an optoelectronic semiconductor component having improved optical characteristics.

Further embodiments provide a method for manufacturing an optoelectronic semiconductor component having improved optical characteristics.

According to at least one embodiment of the optoelectronic semiconductor component the optoelectronic semiconductor component comprises a semiconductor body having a first semiconductor layer, a first cladding layer, a second semiconductor layer, a second cladding layer, an active region arranged between the first cladding layer and the second cladding layer, and a blocking layer arranged between the second cladding layer and the second semiconductor layer.

Preferably, the semiconductor body is an epitaxially grown semiconductor element having a plurality of semiconductor layers. The active region advantageously comprises a pn junction, a double heterostructure, a single quantum well (SQW), or a multiple quantum well (MQW) structure for generating electromagnetic radiation.

For example, the semiconductor body is based on an arsenide compound semiconductor material, a nitride compound semiconductor material or a phosphide compound semiconductor material.

“Based on arsenide compound semiconductor material” means in this context that the semiconductor body or at least a part thereof, particularly preferably at least the active region, preferably comprises AlₙGaₘIn₁₋ₙ₋ₘAs, where 0≤n≤1, 0≤m≤1 and n+m≤1. This material does not necessarily have to have a mathematically exact composition according to the above formula. Rather, it may have one or more dopants as well as additional constituents. For the sake of simplicity, the above formula contains only the essential constituents of the crystal lattice (Al or As, Ga, In), even if these may be partially replaced by small amounts of other substances.

“Based on nitride compound semiconductor material” means in this context that the semiconductor body or at least a part thereof, particularly preferably at least the active region, preferably comprises AlₙGaₘIn₁₋ₙ₋ₘN, where 0≤n≤1, 0≤m≤1 and n+m≤1. This material does not necessarily have to have a mathematically exact composition according to the above formula. Rather, it may have one or more dopants as well as additional constituents. For the sake of simplicity, the above formula contains only the essential constituents of the crystal lattice (Al, Ga, In, N), even if these may be partially replaced by small amounts of other substances.

“Based on phosphide compound semiconductor material” means in this context that the semiconductor body or at least a part thereof, particularly preferably at least the active region, preferably comprises AlₙGaₘIn₁₋ₙ₋ₘP or AsₙGaₘIn₁₋ₙ₋ₘP, where 0≤n≤1, 0≤m≤1 and n+m≤1. In this context, this material does not necessarily have to have a mathematically exact composition according to the above formula. Rather, it may have one or more dopants as well as additional constituents. For the sake of simplicity, however, the above formula contains only the essential constituents of the crystal lattice (Al or As, Ga, In, P), even if these may be partially replaced by small amounts of other substances.

The active region is arranged between the first cladding layer and the second cladding layer. The first and second cladding layers can be arranged directly adjacent to the active region. The first and second cladding layers can enhance the confinement of charge carriers in the active region.

The blocking layer is arranged between the second cladding layer and the second semiconductor layer. For example, the blocking layer is at least partially in direct contact with the second cladding layer and the second semiconductor layer.

According to at least one embodiment of the optoelectronic semiconductor component the active region is designed to emit an electromagnetic radiation in an emission region. Here and in the following the emission region is to be understood as a lateral region of the optoelectronic semiconductor component. The emission region defines a region of the optoelectronic semiconductor component as seen in a top view of the optoelectronic semiconductor component in which electromagnetic radiation is emitted by the optoelectronic semiconductor component. Here and in the following, a top view is to be understood as a view from a direction perpendicular to the main extension direction of the semiconductor body. The emission region is for example an individually controllable region of the semiconductor component.

According to at least one embodiment of the optoelectronic semiconductor component the first semiconductor layer has a first conductivity type. For example, the first semiconductor layer is doped with a first doping material. The first semiconductor layer may have a doping profile. For example, a doping concentration decreases in the first semiconductor layer from a side facing away from the active region in a direction towards the active region. The decreasing doping concentration towards the active region can suppress an unwanted diffusion of dopants from the first semiconductor layer towards the active region. The first conductivity type is for example an n-type conductivity and the second conductivity type is for example a p-type conductivity or vice versa.

According to at least one embodiment of the optoelectronic semiconductor component the second semiconductor layer has a second conductivity type. Preferably, the second conductivity is different from the first conductivity.

According to at least one embodiment of the optoelectronic semiconductor component the first cladding layer and the second cladding layer are nominally undoped. Here and in the following the term “nominally undoped” means that a layer is grown undoped but may be unintentionally doped. Thus, the first and second cladding layers can advantageously hinder a current from spreading from a center to edges of the active region.

According to at least one embodiment of the optoelectronic semiconductor component the blocking layer is formed of a semiconductor material and designed to confine an operating current of the active region to a core region which is spaced apart from the lateral edges of the emission region. By confining the current to the core region which is spaced apart from lateral edges of the emission region, the probability of non-radiative recombination processes can be advantageously reduced.

According to at least one embodiment of the optoelectronic semiconductor component the second semiconductor layer extends at least partially through the blocking layer to the second cladding layer in the core region. In particular, the second semiconductor layer extends completely through the blocking layer to the second cladding layer in the core region.

The second semiconductor layer enables an injection of charge carriers to the second cladding layer in the core region.

According to at least one embodiment of the optoelectronic semiconductor component the optoelectronic semiconductor component comprises a semiconductor body having a first semiconductor layer, a first cladding layer, a second semiconductor layer, a second cladding layer, an active region arranged between the first cladding layer and the second cladding layer and a blocking layer arranged between the second cladding layer and the second semiconductor layer, wherein
the active region is designed to emit an electromagnetic radiation in an emission region,
the first semiconductor layer has a first conductivity type,
the second semiconductor layer has a second conductivity type,
the first cladding layer and the second cladding layer are nominally undoped,
the blocking layer is formed of a semiconductor material and designed to confine an operating current of the active region to a core region, and
the second semiconductor layer extends at least partially through the blocking layer to the second cladding layer in the core region, which is spaced apart from the lateral edges of the emission region.

An optoelectronic semiconductor component described herein is, inter alia, based on the following considerations: At the lateral edges of an emission region of an optoelectronic semiconductor component a higher density of defects can be observed. These defects, such as dangling bonds, are often a source of non-radiative recombination processes which lead to an unwanted drop in efficiency of the optoelectronic semiconductor component. This problem gets more important when the lateral size of an emission region decreases, as the area-to-circumference ratio gets more unfavorable.

The optoelectronic semiconductor component described herein is, among other things, based on the idea of forming a blocking layer in the semiconductor body which is formed of a semiconductor material and designed to confine the operating current of the active region to a core region which is spaced apart from the lateral edges of the emission region. By confining the current to the core region the probability of non-radiative recombination processes at the lateral edges of the emission region can be advantageously reduced.

According to at least one embodiment of the optoelectronic semiconductor component the core region is located at the center of the emission region in a top view. The centered arrangement of the core region allows the core region to be as far away as possible from the lateral edges of the emission region. Consequently, a charge carrier density at the lateral edges of the emission region is particularly low, which reduces a non-radiative recombination probability.

According to at least one embodiment of the optoelectronic semiconductor component the blocking layer is undoped or has the first conductivity type. Thus, preferably, the blocking layer is doped with an equal conductivity type as the layer arranged adjacent to the active region opposite to the blocking layer, namely the first cladding layer. A blocking layer which is undoped or has the first conductivity type creates a barrier layer at the interface with the second cladding layer. This reduces or suppresses an injection of charge carriers in the region of the blocking layer. In particular, if the blocking layer is nominally undoped, the recess only has to partially penetrate the blocking layer for the device to work.

According to at least one embodiment of the optoelectronic semiconductor component the second semiconductor layer extends to the second cladding layer. Advantageously, the second cladding layer is not affected by the second semiconductor layer.

According to at least one embodiment of the optoelectronic semiconductor component the second semiconductor layer extends into the second cladding layer and ends therein. In other words, the second semiconductor layer does not completely penetrate the second cladding layer. Advantageously, the second cladding layer is not divided by the recess and the active region remains unaffected.

According to at least one embodiment of the optoelectronic semiconductor component the blocking layer comprises at least one first blocking layer of the first conductivity type and at least one second blocking layer of the second conductivity type. Preferably, the first blocking layers and the second blocking layers are arranged alternately. A plurality of different layers can improve the current blocking abilities of the blocking layer, because a plurality pf barrier layers can be formed in the blocking layer.

According to at least one embodiment of the optoelectronic semiconductor component the layer of the blocking layer which is closest to the second cladding layer is a first blocking layer. Thus, in other words, the layer of the blocking layer which is closest to the second cladding layer is doped with the same conductivity type as the first semiconductor layer. The arrangement of a first blocking layer having a first conductivity type closest to the second cladding layer can avoid an unwanted current spreading in the vicinity of the active region. In particular, the cladding layers and the active region are nominally undoped, which further prevents current spreading in these layers.

According to at least one embodiment of the optoelectronic semiconductor component, the semiconductor component comprises a second contact element which electrically contacts the second semiconductor layer and is arranged in alignment with the core region. The injection of current to the second semiconductor layer can be further confined to the core region by the second contact element.

In particular, the second contact element is arranged exclusively in the core region.

According to at least one embodiment of the optoelectronic semiconductor component, the semiconductor component comprises a connecting element which is arranged between the first contact layer and the first semiconductor layer. The connecting element is preferably aligned with the core region. In particular, the connecting element is formed exclusively in the core region. For example, the connecting element comprises a thin layer of gold and germanium or implanted silicon, for example Si plasma implant. The connecting element is preferably transparent. The connecting element can provide for an ohmic contact between the first contact layer and the first semiconductor layer. Thus, a current injection into the first semiconductor layer can be confined to the area of the connecting element. In particular, such a connecting element is suitable where the first semiconductor layer is formed using n-doped InGaAlP or n-doped GaN.

According to at least one embodiment of the optoelectronic semiconductor component, the semiconductor component comprises an insulating element which is arranged between the first contact layer and the first semiconductor layer. Preferably, the first semiconductor layer is partially removed, for example by etching. In particular, the first semiconductor layer is partially removed except for an area which is aligned with the core region. The removal of the first semiconductor layer advantageously decreases a current spreading in lateral directions. Consequently, a current flow is confined to the core region.

Additionally, a current injection can be further confined to the core region by the insulating element, which is arranged around the core region, where the first semiconductor layer is removed.

According to at least one embodiment of the optoelectronic semiconductor component the first semiconductor layer comprises a contact defining recess extending from the side remote from the active region towards the first cladding layer. The contact defining recess further confines a current injection in the first semiconductor layer. For example, the first semiconductor layer comprises a variable doping concentration. In particular, the concentration of a dopant in the first semiconductor layer decreases in a direction starting from a side remote of the active region towards the active region. By introducing the contact defining recess, an upper part of the first semiconductor layer is at least partially removed which comprises the highest doping concentration and thus forms the best ohmic contact to a further contact element. By the removal of the upper part, the injection of charge carriers into the first semiconductor layer can be limited to the remaining part of the first semiconductor layer without the contact defining recess.

According to at least one embodiment of the optoelectronic semiconductor component the contact defining recess only extends in the first semiconductor layer.

Advantageously, the first cladding layer remains completely intact.

According to at least one embodiment of the optoelectronic semiconductor component the contact defining recess extends around the core region. In other words, the contact defining recess is formed in such a way that a contact protrusion of the first semiconductor layer which is aligned with the core region remains. This enables an injection of charge carriers in the core region.

According to at least one embodiment of the optoelectronic semiconductor component the optoelectronic semiconductor component comprises a plurality of individually addressable emission regions. Such an optoelectronic semiconductor component is for example suitable for a display device comprising a plurality of pixels.

According to at least one embodiment of the optoelectronic semiconductor component each emission region comprises a core region, which is spaced apart from the lateral edges of said emission region. Each core region confines the current injection to a core region of each emission region. The current confinement can decrease the non-radiative recombination probability and thus increase efficiency.

According to at least one embodiment of the optoelectronic semiconductor component the emission regions each have a lateral extension of less than 100 μm, preferably of less than 50 μm and particularly preferably of less than 5 μm. Small lateral extensions of the emission region enable high resolution displays.

A method for manufacturing an optoelectronic semiconductor component is also disclosed. The method for manufacturing an optoelectronic semiconductor component is particularly suitable for manufacturing an optoelectronic semiconductor component described herein. This means that all features disclosed in connection with the optoelectronic semiconductor component are also disclosed for the method for manufacturing an optoelectronic semiconductor component and vice versa.

According to at least one embodiment of the method for manufacturing an optoelectronic semiconductor component a semiconductor body is provided, having a first semiconductor layer, a first cladding layer, a second cladding layer, an active region arranged between the first cladding layer and the second cladding layer, and a blocking layer arranged on the second cladding layer remote from the active region, wherein the first semiconductor layer has a first conductivity type, the first cladding layer and the second cladding layer are nominally undoped, the blocking layer is formed of a semiconductor material and designed to confine an operating current of the active region to a core region. The blocking layer is preferably undoped or has the first conductivity type.

According to at least one embodiment of the method for manufacturing an optoelectronic semiconductor component the core region is defined by forming at least one core recess, which is spaced apart from the lateral edges of the semiconductor body and can partially or completely penetrate the blocking layer. The core recess can be formed by wet etching or by a dry etching. In particular, when a dry etching method is used, a subsequent wet etching step can be useful to remove damages from the dry etching.

For the use of a wet etching method, a variety of etch stop layers can be used to define a depth of the core recess. For example a combination of an etch stop layer made from InGaAIP for a layer made from InAlP can be used.

According to at least one embodiment of the method for manufacturing an optoelectronic semiconductor component a second semiconductor layer having a second conductivity type is arranged in the core recess. The second semiconductor layer is for example epitaxially grown. Preferably, the second semiconductor layer has a controlled doping profile.

According to at least one embodiment of the method for manufacturing an optoelectronic semiconductor component the core recess does not completely penetrate the second cladding layer. Advantageously, the second cladding layer is not separated by the core recess.

According to at least one embodiment of the method for manufacturing an optoelectronic semiconductor component the core recess extends as far as the second cladding layer. In other words, the core recess does not extend into the second cladding layer.

Advantageously, the second cladding layer remains unaffected by the core recess.

According to at least one embodiment of the method for manufacturing an optoelectronic semiconductor component a second mask is arranged on the second semiconductor layer, wherein the second mask is formed by a dielectric material. A dielectric material is to be understood as an electrically insulating material that can be polarized by an applied electric field, for example a photoresist.

For example the second mask is formed by one of the following materials: photoresist, silicon oxide, aluminum oxide, silicon nitride. Silicon oxide, aluminum oxide, silicon nitride can advantageously serve as an etch mask and at the same time withstand the high temperatures of following regrowth and/or passivation method steps.

According to at least one embodiment of the method for manufacturing an optoelectronic semiconductor component a plurality of isolating recesses are introduced, which extend from the second semiconductor layer to the first semiconductor layer to divide the semiconductor body into a plurality of individually controllable emission regions. The emission regions are electrically and optically separated from each other by the isolating recesses.

According to at least one embodiment of the method for manufacturing an optoelectronic semiconductor component the isolating recesses are introduced by dry etching. A dry etching method enables a high aspect ratio and a high etch rate. In a further method step a possible damage of the dry etching step can be removed by wet etching for example, to further reduce a non-radiative recombination probability.

An optoelectronic semiconductor component described herein is particularly suitable for use in so-called “smart eyewear products” with which augmented reality (AR) or virtual reality (VR) units are realized, or any other microLED applications.

### BRIEF DESCRIPTION OF THE DRAWINGS

Further advantages and advantageous designs and further developments of the optoelectronic module will become apparent from the following exemplary embodiments, which are described below in association with the figures.

FIGS. 1A to 1F show schematic cross-sectional views of an optoelectronic semiconductor component described herein according to a first exemplary embodiment in different steps of a method for its manufacture;

FIG. 2 shows a schematic cross-sectional view of an optoelectronic semiconductor component described herein according to a second exemplary embodiment;

FIG. 3 shows a schematic cross-sectional view of an optoelectronic semiconductor component described herein according to a third exemplary embodiment;

FIG. 4 shows a schematic cross-sectional view of an optoelectronic semiconductor component described herein according to a fourth exemplary embodiment;

FIG. 5 shows a schematic cross-sectional view of an optoelectronic semiconductor component described herein according to a fifth exemplary embodiment;

FIG. 6 shows a schematic cross-sectional view of an optoelectronic semiconductor component described herein according to a sixth exemplary embodiment;

FIG. 7 shows a schematic cross-sectional view of an optoelectronic semiconductor component described herein according to a seventh exemplary embodiment; and

FIG. 8 shows a schematic cross-sectional view of an optoelectronic semiconductor component described herein according to an eighth exemplary embodiment.

Identical, similar or equivalent elements are marked with the same reference signs in the figures. The figures and the proportions of the elements represented in the figures among each other are not to be considered as true to scale. Rather, individual elements may be oversized for better representability and/or comprehensibility.

### DETAILED DESCRIPTION OF ILLUSTRATIVE EMBODIMENTS

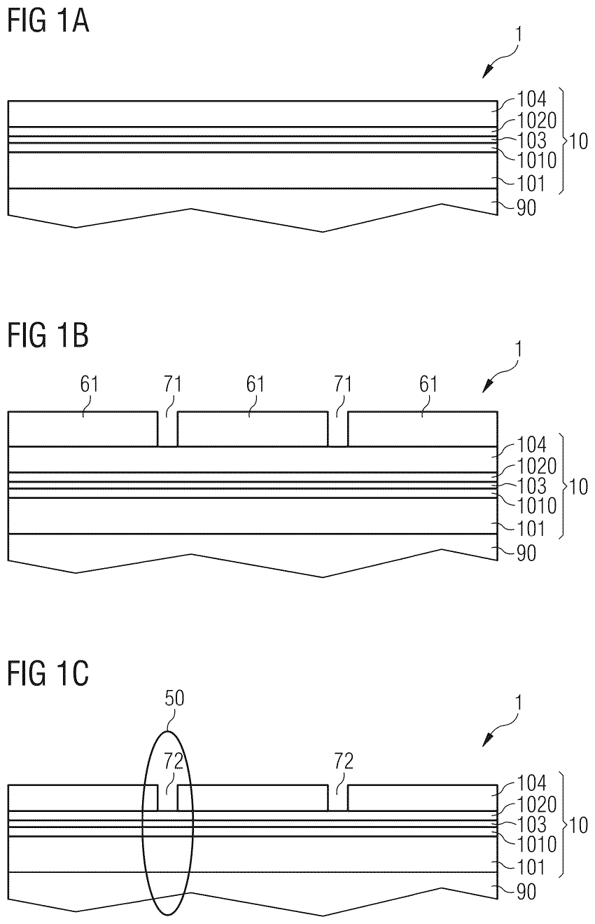

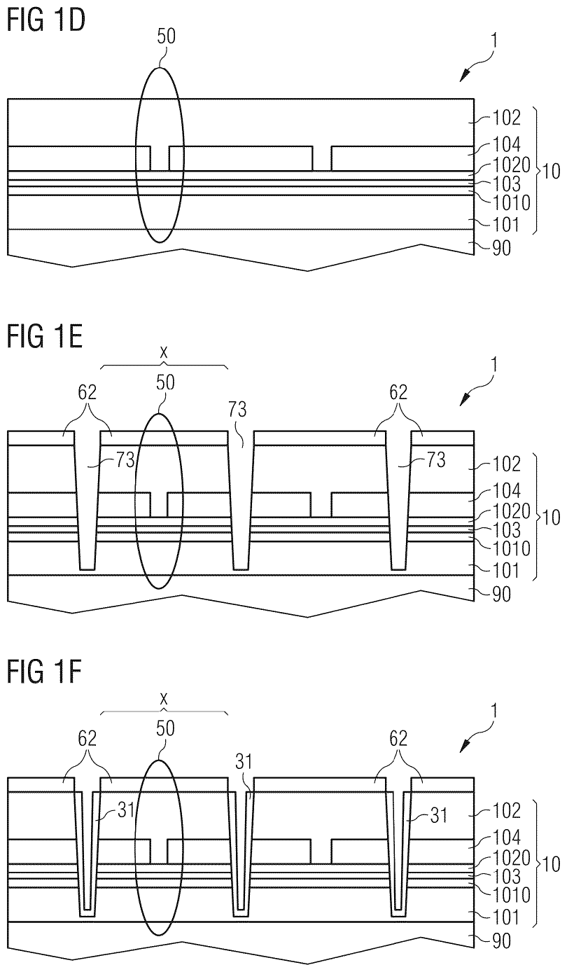

FIG. 1A shows a schematic cross-sectional view of an optoelectronic semiconductor component 1 described herein according to a first exemplary embodiment in a first step of a method for its manufacture. In the first step, a semiconductor body 10 is provided on a growth substrate 90.

The semiconductor body 10 is an epitaxially grown structure on the growth substrate 90. The semiconductor body 10 comprises a first semiconductor layer 101, a first cladding layer 1010, a second cladding layer 1020, an active region 103 arranged between the first cladding layer 1010 and the second cladding layer 1020 and a blocking layer 104 arranged on the second cladding layer 1020 remote from the active region 103. The active region 103 is configured to generate electromagnetic radiation, preferably in a visible spectral range, during operation.

The first semiconductor layer 101 has a first conductivity type. The first semiconductor layer 101 can have a doping profile. In particular, a doping concentration can decrease from a side of the first semiconductor layer 101 facing away from the active region 103 towards the active region 103. This doping profile can avoid unwanted diffusion of dopants from the first semiconductor layer 101 into the active region 103. The first cladding layer 1010 and the second cladding layer 1020 are nominally undoped.

The blocking layer 104 is formed of a semiconductor material and designed to confine an operating current of the active region 103 to a core region 50.

FIG. 1B shows a schematic cross-sectional view of an optoelectronic semiconductor component 1 described herein according to a first exemplary embodiment in a further step of a method for its manufacture. In this further step, a first mask layer 61 is arranged on the side of the blocking layer 104 facing away from the active region 103. The first mask layer 61 can be formed from a photoresist material. Further, the first mask layer 61 gets patterned by introducing an opening 71 into the first mask layer 61.

FIG. 1C shows a schematic cross-sectional view of an optoelectronic semiconductor component 1 described herein according to a first exemplary embodiment in a further step of a method for its manufacture. In this further step, the core region 50 is defined by forming at least one core recess 72 in the blocking layer 104. The core recess 72 is spaced apart from the later defined lateral edges of an emission region X and completely penetrates the blocking layer 104. According to an alternative embodiment, the core recess 72 only partially penetrates the blocking layer 104. The core recess 72 stops at approximately the second cladding layer 1020. The first mask layer 61 is removed after the core recesses 72 are formed.

FIG. 1D shows a schematic cross-sectional view of an optoelectronic semiconductor component 1 described herein according to a first exemplary embodiment in a further step of a method for its manufacture. According to this further step, a second semiconductor layer 102 having a second conductivity type is arranged in the core recess 72. The second semiconductor layer 102 preferably is in direct contact with the second cladding layer 1020 in the core recess 72.

In particular, the second semiconductor layer 102 is formed as an epitaxially grown layer having a controlled doping profile. Preferably, a doping concentration in the second semiconductor layer 102 decreases from a side of the second semiconductor layer 102 facing away from the active region 103 towards the active region 103. This doping profile can avoid unwanted diffusion of dopants from the second semiconductor layer 102 into the active region 103.

FIG. 1E shows a schematic cross-sectional view of an optoelectronic semiconductor component 1 described herein according to a first exemplary embodiment in a further step of a method for its manufacture. According to this step, a second mask layer 62 is arranged on a side of the second semiconductor layer 102 facing away from the active region 103. The second mask layer 62 can be formed with a dielectric material, such as silicon dioxide for example. Isolating recesses 73 are formed in the semiconductor body 10 aligned to the recesses in the structured second mask layer 62. The second mask layer 62 could remain in the final optoelectronic semiconductor component 1 or can alternatively be removed from the optoelectronic semiconductor component 1 in a subsequent step.

The isolating recesses 73 start from the second mask layer 62 and are completely penetrating the second semiconductor layer 102, the blocking layer 104, the second cladding layer 1020, the active region 103 and the first cladding layer 1010. The isolating recesses 73 end in the first semiconductor layer 101. By means of the isolating recesses 73, the semiconductor body 10 is divided into a plurality of individual emission regions X.

The emission regions X each comprise at least one core region 50. The emission regions X are optically and electrically isolated from each other by the isolating recesses 73.

FIG. 1F shows a schematic cross-sectional view of an optoelectronic semiconductor component 1 described herein according to a first exemplary embodiment in a further step of a method for its manufacture. This further step concerns the arrangement of a first insulating structure 31 into the isolating recesses 73. The first insulating structure 31 is formed with an electrically insulating material, preferably a dielectric material.

In particular, the first insulating structure 31 comprises a plurality of layers. Such a multilayer structure can advantageously increase an optical reflectivity of the first insulating structure 31, which results in reduced optical crosstalk between adjacent emission regions X and enhanced light emission out of the final device.

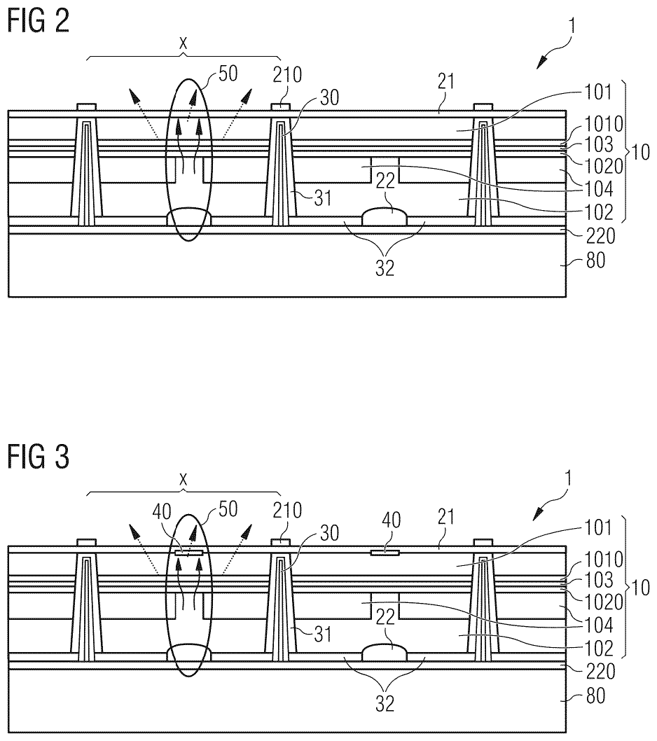

FIG. 2 shows a schematic cross-sectional view of an optoelectronic semiconductor component 1 described herein according to a second exemplary embodiment. The optoelectronic semiconductor component 1 comprises a semiconductor body 10 which is arranged on a carrier 80.

The semiconductor body 10 has a first semiconductor layer 101, a first cladding layer 1010, a second semiconductor layer 102, a second cladding layer 1020, an active region 103 arranged between the first cladding layer 1010 and the second cladding layer 1020, and a blocking layer 104 arranged between the second cladding layer 1020 and the second semiconductor layer 102.

The active region 103 is designed to emit an electromagnetic radiation in an emission region X. The emission region is an individually controllable region of the optoelectronic semiconductor component 1. In other words, each emission region X can be controlled without affecting any other emission regions X of the optoelectronic semiconductor component 1. This is particularly suitable for a display device having a plurality of individual emission regions X each acting as a pixel or a sub pixel of the display device.

The first semiconductor layer 101 has a first conductivity type, while the second semiconductor layer 102 has a second conductivity type. The blocking layer 104 is formed of a semiconductor material and designed to confine an operating current of the active region 103 to a core region 50. The first cladding layer 1010 and the second cladding layer 1020 are preferably nominally undoped.

The second semiconductor layer 102 extends completely through the blocking layer 104 to the second cladding layer 1020 in the core region 50, which is spaced apart from the lateral edges of the emission region X. Charge carriers can be injected into the active region 103 through the second semiconductor layer 102.

The emission regions X are electrically and optically insulated from each other by reflective elements 30 and first insulating structures 31 which are arranged in recesses between the emission regions X. For example the reflective elements 30 are formed with a highly optical reflective material, such as a metal. In particular, the first insulating structure 31 comprises a plurality of layers. In particular, the insulating structure 31 comprises dielectric or other transparent layers. Such a multilayer structure can advantageously increase an optical reflectivity of the first insulating structure 31, which results in reduced optical crosstalk between adjacent emission regions X, and also enhances emission out of the final device.

Further, the optoelectronic semiconductor component 1 comprises a first contact layer 21 to electrically contact the first semiconductor layer 101. The first contact layer 21 is arranged on the side of the first semiconductor layer 101 facing away from the active region 103. In particular, the first contact layer 21 is formed with a radiation permeable material, such as a transparent conductive oxide (TCO) or a semiconducting material. The first contact layer 21 is electrically connected to first contact elements 210 which can be formed by a metal.

The second semiconductor layer 102 is electrically connected to a second contact element 22 which is arranged on a side of the second semiconductor layer 102 facing away from the active region 103. The second contact element 22 is arranged aligned with the core region 50 and laterally surrounded by a second insulating structure 32. The second insulating structure 32 is formed with an electrically insulating material. In particular, the second insulating structure 32 comprises a plurality of layers. Such a multilayer structure can advantageously increase an optical reflectivity of the second insulating structure 32. The second contact element 22 confines a current injection into the second semiconductor layer 102 to a region which is aligned with the core region 50. The second contact element 22 can be contacted by a second contact layer 220 arranged between the second contact element 22 and the carrier 80.

The carrier 80 can for example be a wafer in CMOS technology comprising a plurality of switches and/or circuits. In particular, the carrier 80 provides for an individual control of each emission region X.

FIG. 3 shows a schematic cross-sectional view of an optoelectronic semiconductor component 1 described herein according to a third exemplary embodiment. For the most part, the third embodiment corresponds to the second embodiment shown in FIG. 2. Additionally, the third embodiment comprises a connecting element 40 which is arranged between the first contact layer 21 and the first semiconductor layer 101.

The connecting element 40 is aligned with the core region 50 and formed exclusively in the core region 50. For example, the connecting element 40 comprises a thin layer of gold and germanium or implanted silicon, for example Si plasma implant. The connecting element 40 is in particular transparent. The connecting element 40 provides for an ohmic contact between the first contact layer 21 and the first semiconductor layer 101. Thus, a current injection into the first semiconductor layer 101 can be confined to the connecting element 40. In particular, such a connecting element 40 is suitable where the first semiconductor layer 101 is formed using n-doped InGaAIP or n-doped GaN.

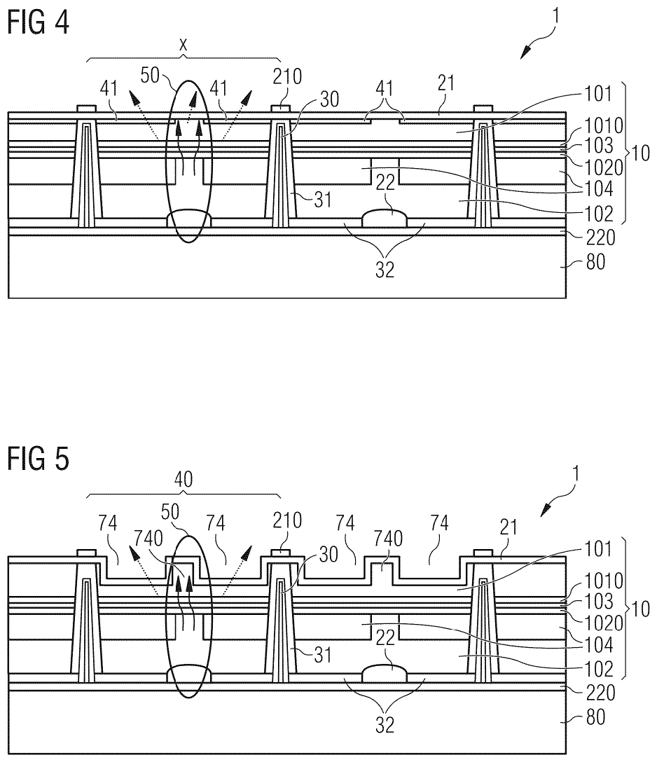

FIG. 4 shows a schematic cross-sectional view of an optoelectronic semiconductor component 1 described herein according to a fourth exemplary embodiment. For the most part, the fourth embodiment corresponds to the second embodiment shown in FIG. 2. Additionally, the fourth embodiment comprises an insulating element 41 which is arranged between the first contact layer 21 and the first semiconductor layer 101.

The first semiconductor layer 101 is partially removed, for example by etching. In particular, the first semiconductor layer 101 is partially removed except for an area which is aligned with the core region 50. The removal of the first semiconductor layer 101 advantageously decreases a current spreading in lateral directions. Consequently, a current flow is confined to the core region 50.

Additionally, a current injection is further confined to the core region 50 by the insulating element 41, which is arranged around the core region 50, where the first semiconductor layer 101 is removed.

FIG. 5 shows a schematic cross-sectional view of an optoelectronic semiconductor 1 component described herein according to a fifth exemplary embodiment. For the most part, the fifth embodiment corresponds to the second embodiment shown in FIG. 2. Additionally, the optoelectronic semiconductor component 1 comprises a contact defining recess 74 in the first semiconductor layer 101. The contact defining recess 74 only extends in the first semiconductor layer 101. Advantageously, the first cladding layer 1010 remains completely intact.

The contact defining recess 74 extends from the side of the first semiconductor layer 101 remote from the active region 103 towards the first cladding layer 1010. The contact defining recess 74 further confines a current injection into the first semiconductor layer 101. For example, the first semiconductor layer 101 comprises a variable doping concentration. In particular, the concentration of a dopant in the first semiconductor layer 101 decreases in a direction starting from the side remote of the active region 103 towards the active region 103.

By introducing the contact defining recess 74 into the first semiconductor layer 101, an upper part of the first semiconductor layer 101 is at least partially removed which comprises the highest doping concentration and thus forms the best ohmic contact to the first contact layer 21 and a contact protrusion 740 remains. By the removal of the upper part of the first semiconductor layer 101, the injection of charge carriers into the first semiconductor layer 101 can be limited to the remaining contact protrusion 740 of the first semiconductor layer 101. In other words, the contact defining recess 74 comprises a depth, which is sufficient to reach a region of the first semiconductor layer 101 having a doping concentration which is too low to form an ohmic contact with a material of the first contact layer 21.

The contact defining recess 74 extends around the contact protrusion 740 in the core region 50. In other words, the contact defining recess 74 is formed in such a way that the contact protrusion 740 of the first semiconductor layer 101 is aligned with the core region 50. In particular, the contact protrusion 740 does not project beyond the core region 50 in its lateral directions.

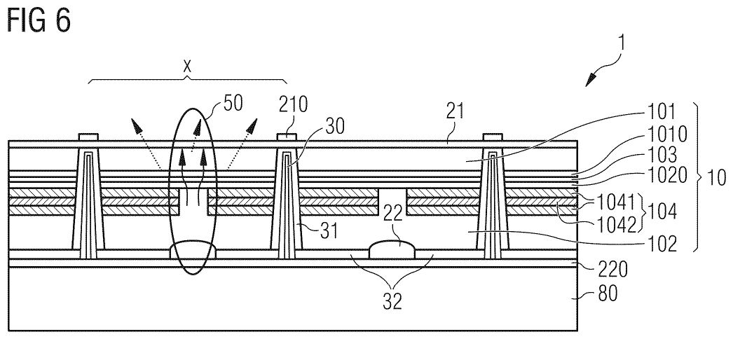

FIG. 6 shows a schematic cross-sectional view of an optoelectronic semiconductor component 1 described herein according to a sixth exemplary embodiment. For the most part, the sixth embodiment corresponds to the second embodiment shown in FIG. 2. The blocking layer 104 according to the sixth embodiment comprises first blocking layers 1041 of a first conductivity type and a second blocking layer 1042 of a second conductivity type. The second blocking layer 1042 is arranged between the first blocking layers 1041.

Preferably, first blocking layers 1041 of the first conductivity and second blocking layers 1042 of the second conductivity are arranged alternately. A plurality of different layers can improve the current blocking abilities of the blocking layer 104 because a plurality of barrier layers can be formed in the blocking layer 104.

The layer of the blocking layer 104 which is closest to the second cladding layer 1020 is a first blocking layer 1041. Thus, the layer of the blocking layer 104 which is closest to the second cladding layer 1020 is doped with the same conductivity type as the first semiconductor layer 101. The arrangement of a first blocking layer 1041 adjacent to the second cladding layer 1020, and having a first conductivity type, can avoid an unwanted current spreading in the vicinity of the active region 103.

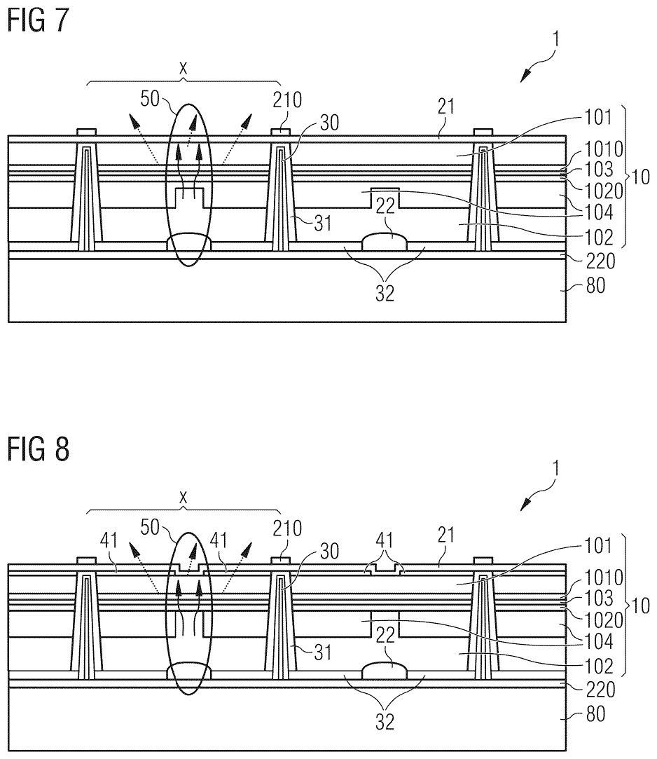

FIG. 7 shows a schematic cross-sectional view of an optoelectronic semiconductor component 1 described herein according to a seventh exemplary embodiment. For the most part, the seventh embodiment corresponds to the second embodiment shown in FIG. 2.

However, the second semiconductor layer 102 according to the seventh exemplary embodiment only partially extends through the blocking layer 104. The second semiconductor layer 102 is not in direct contact with the second cladding layer 1020. For example, dopants from the second semiconductor layer 102 could diffuse into the nominally undoped blocking layer 104 which would lead to a sufficient conductivity in the core region 50. Thus, a current injection is advantageously confined to the core region 50.

FIG. 8 shows a schematic cross-sectional view of an optoelectronic semiconductor component 1 described herein according to an eighth exemplary embodiment. For the most part, the eighth embodiment corresponds to the second embodiment shown in FIG. 2. Additionally, the eighth embodiment comprises an insulating element 41 which is arranged between the first contact layer 21 and the first semiconductor layer 101.

The insulating element 41 is formed by an electrically insulating material. The insulating element 41 comprises a recess which is aligned with the core region 50. Thus, the first contact layer 21 only connects to the first semiconductor layer 101 in the core region 50 and a current injection into the first semiconductor layer 101 can be confined to the core region 50.

Furthermore, a combination of the insulating element 41 and the connecting element 40 in an optoelectronic semiconductor component would also be conceivable.

The invention described herein is not limited by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

1.-18. (canceled)

19. An optoelectronic semiconductor component comprising:
a semiconductor body having a first semiconductor layer, a first cladding layer, a second semiconductor layer, a second cladding layer, an active region arranged between the first cladding layer and the second cladding layer, and a blocking layer arranged between the second cladding layer and the second semiconductor layer,
wherein the active region is configured to emit an electromagnetic radiation in an emission region,
wherein the first semiconductor layer has a first conductivity type,
wherein the second semiconductor layer has a second conductivity type,
wherein the first cladding layer and the second cladding layer are nominally undoped,
wherein the blocking layer is formed of a semiconductor material and configured to confine an operating current of the active region to a core region,
wherein the second semiconductor layer extends at least partially through the blocking layer to the second cladding layer in the core region, which is spaced apart from lateral edges of the emission region,
wherein the blocking layer comprises at least one first blocking layer of the first conductivity type and at least one second blocking layer of the second conductivity type, and wherein a layer of the blocking layer, which is closest to the second cladding layer, is the first blocking layer.

20. The optoelectronic semiconductor component according to claim 19, wherein the core region is located at a center of the emission region in a top view.

21. The optoelectronic semiconductor component according to claim 19, wherein the blocking layer is undoped or has the first conductivity type.

22. The optoelectronic semiconductor component according to claim 19, wherein the second semiconductor layer extends to the second cladding layer.

23. The optoelectronic semiconductor component according to claim 22, wherein the second semiconductor layer extends into the second cladding layer and ends therein.

24. The optoelectronic semiconductor component according to claim 19, further comprising a second contact element, which electrically contacts the second semiconductor layer and is aligned with the core region.

25. The optoelectronic semiconductor component according to claim 19, wherein the first semiconductor layer comprises a contact defining recess extending from a side remote from the active region towards the first cladding layer.

26. The optoelectronic semiconductor component according to claim 25, wherein the contact defining recess only extends in the first semiconductor layer.

27. The optoelectronic semiconductor component according to claim 25, wherein the contact defining recess extends around the core region.

28. The optoelectronic semiconductor component according to claim 19, comprising a plurality of individually addressable emission regions.

29. The optoelectronic semiconductor component according to claim 28, wherein each emission region comprises a core region, which is spaced apart from the lateral edges of the emission region.

30. The optoelectronic semiconductor component according to claim 28, wherein each of the emission regions has a lateral extension of less than 100 μm.

31. A method for manufacturing an optoelectronic semiconductor component, the comprising:
providing a semiconductor body having a first semiconductor layer, a first cladding layer, a second cladding layer, an active region arranged between the first cladding layer and the second cladding layer, and a blocking layer arranged on the second cladding layer remote from the active region, wherein the first semiconductor layer has a first conductivity type, the first cladding layer and the second cladding layer are nominally undoped, the blocking layer is formed of a semiconductor material and configured to confine an operating current of the active region to a core region;
defining the core region by forming at least one core recess, which is spaced apart from lateral edges of the semiconductor body and partially or completely penetrates the blocking layer; and
arranging a second semiconductor layer having a second conductivity type in the core recess,
wherein the blocking layer comprises at least one first blocking layer of the first conductivity type and at least one second blocking layer of the second conductivity type, and
wherein a layer of the blocking layer, which is closest to the second cladding layer is the first blocking layer.

32. The method according to claim 31, wherein the core recess does not completely penetrate the second cladding layer.

33. The method according to claim 31, wherein the core recess extends as far as the second cladding layer.

34. The method according to claim 31, further comprising arranging a second mask on the second semiconductor layer, the second mask being formed by a photoresist or dielectric material.

35. The method according to claim 34, further comprising introducing a plurality of isolation recesses, which extend from the second semiconductor layer to the first semiconductor layer to divide the semiconductor body into a plurality of individually controllable emission regions.

36. The method according to claim 35, wherein the isolation recesses are introduced by dry etching.
